(19) United States
(12) Patent Application Publication
(10) Pub. No.: US 2014/0009047 A1
(43) Pub. Date: Jan. 9, 2014

(54) CABINET FOR ELECTRONIC APPARATUS AND AN ELECTRONIC APPARATUS

(71) Applicant: NEC Personal Computers, Ltd, Tokyo (JP)

(72) Inventor: Tsunenori Yanagisawa, Tokyo (JP)

(21) Appl. No.: 13/928,867

(22) Filed: Jun. 27, 2013

(30) Foreign Application Priority Data
Jul. 4, 2012 (JP) 2012-150947

(51) Int. Cl. H05K 5/04

(52) U.S. Cl. CPC H05K 5/04
USPC 312/223.1

(57) ABSTRACT

In a cabinet for electronic apparatus, even when Mg—Li alloy is employed to reduce weight of the cabinet and the cabinet is molded through presswork by using the Mg—Li alloy, neither a rough surface nor a crack appears in any bent portion of the cabinet. In a cabinet for electronic apparatus including at least one surface formed by conducting presswork for Mg—Li alloy, the surface has a plate thickness t (mm) in a range of 0.4≦t≦2.0, at least one bent portion between at least two of the surfaces has a radius of curvature r (mm) on an inside of the bent portion in a range of t≦r, and at least one side surface standing relative to a bottom surface selected from the surfaces has a height H (mm) in a range of 0≦H≦r+4.

### BACKGROUND OF THE INVENTION

1. Field of the Invention

The present invention relates to a cabinet for electronic apparatus formed through presswork by use of a magnesium (Mg)-lithium (Li) alloy and an electronic apparatus including the same.

2. Description of the Prior Art

It has been required to reduce thickness and weight of electronic apparatuses such as a mobile notebook personal computer. Hence, this results in requirements to reduce thickness and weight of the cabinet for such electronic apparatuses. To secure a good design and rigidity of the cabinet, light metal having a low specific gravity such as magnesium having a specific gravity of 1.8 is employed as a material of the cabinet. For example, Japanese Patent Laid-Open Ser. No. 2011-156587 describes an invention regarding an exterior part of a cabinet formed in the shape of a container by use of presswork such as drawing for a magnesium alloy.

For recent electronic apparatuses such as a mobile notebook personal computer, due to requirements of downsizing and higher performance of products of such apparatuses in addition to requirements of reduction in thickness and weight of the cabinet, parts internally arranged therein are downsized and are mounted with a higher integration ratio (higher mounting efficiency).

Also, Mg—Li alloy less in the specific gravity than magnesium, for example, LA141 having a specific gravity of 1.34 has been recently put to the market. If it is possible to use the alloy for the cabinet of a portable electronic apparatus, the weight thereof will be further reduced.

However, when the Mg—Li alloy is employed to mold the cabinet for electronic apparatuses such as a mobile notebook personal computer through the presswork, there occurs a problem, which has not been reported in the presswork conducted by use of the magnesium alloy described in Japanese Patent Laid-Open Ser. No. 2011-156587.

Assume, for example, that in the production of the cabinet, the thickness thereof is reduced by using a metallic plate of predetermined thickness including Mg—Li alloy and the metallic plate is pressed such that a bent portion as a boundary between a bottom surface and a side surface of the cabinet has a possibly small radius of curvature. In this situation, there exists a problem in which due to the reduced thickness of the plate, the bent portion is extended to cause a rough surface and/or a crack.

### SUMMARY OF THE INVENTION

It is therefore an object of the present invention to provide a cabinet for electronic apparatus which is devised in consideration of the problem and in which when the presswork is conducted for the metallic plate including Mg—Li alloy adopted to further reduce the thickness, neither the rough surface nor the crack appears in the bent portion of the cabinet.

In accordance with the present invention made through research and development by the inventors to meet the requirements described above, there is provided a cabinet for electronic apparatus including at least one surface formed by conducting presswork for magnesium-lithium alloy, wherein the surface has a plate thickness t (mm) in a range of 0.4≦t≦2.0, at least one bent portion between at least two of the surfaces has a radius of curvature r (mm) on an inside of the bent portion in a range of t≦r, and at least one side surface standing relative to a bottom surface selected from the surfaces has a height H (mm) in a range of 0≦H≦r+4.

In accordance with the present invention, the cabinet is much more reduced in weight and it is possible to prevent the rough surface and the crack in the bent portion of the cabinet.

### BRIEF DESCRIPTION OF THE DRAWINGS

The objects and features of the present invention will become more apparent from the consideration of the following detailed description taken in conjunction with the accompanying drawings in which:

FIG. 1 is a perspective view schematically showing a bottom case 10 of a computer 1 in a first embodiment of the present invention;

FIG. 2 is a cross-sectional view of a bent portion of the bottom case 10;

FIG. 3A is an image of a bent portion with a phenomenon of a rough surface appearing in a bent portion when the radius of curvature of the bent portion is outside the allowable range in the bottom case 10;

FIG. 3B is an image of a bent portion without any rough surface in a bent portion having an appropriate radius of curvature in the bottom case 10;

FIG. 4A is a schematic diagram showing installability of an electronic part or the like when the radius of curvature is small in the bent portion of the bottom case;

FIG. 4B is a schematic diagram showing installability of an electronic part or the like when the radius of curvature is large in the bent portion of the bottom case;

FIG. 4C is a schematic diagram showing installability of an electronic part or the like when the radius of curvature is small in the bent portion of the bottom case;

FIG. 4D is a schematic diagram showing installability of an electronic part or the like when the radius of curvature is large in the bent portion of the bottom case;

FIG. 5 is a simplified perspective view of a bottom case 110 of a computer 50 in a second embodiment of the present invention; and

FIG. 6 is a plan view of the bottom case 110 in accordance with the second embodiment.

### DESCRIPTION OF THE EMBODIMENTS

### First Embodiment

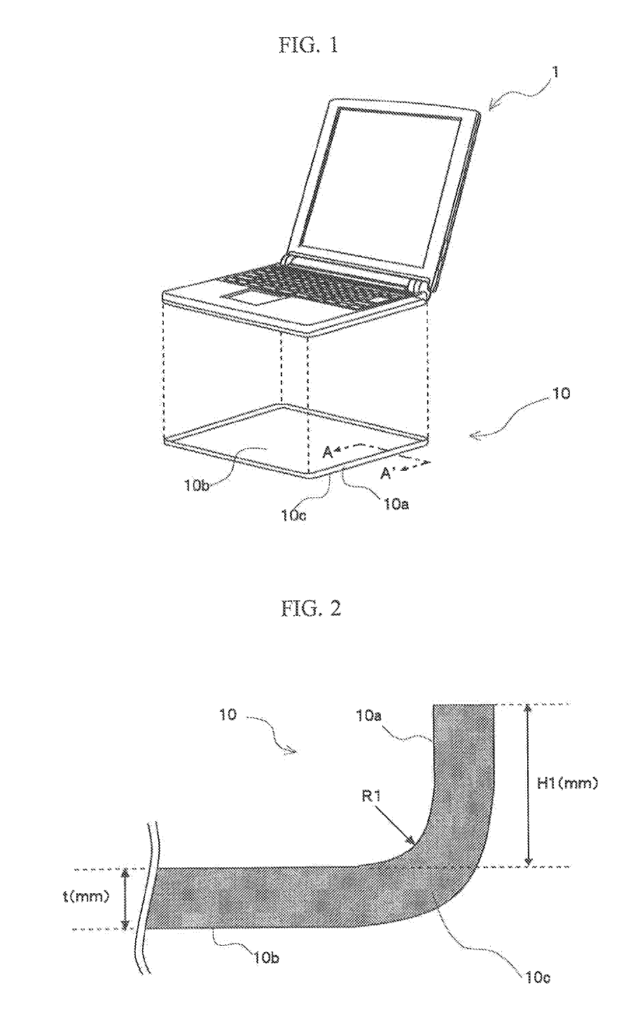

Referring now to the drawings, description will be given of a cabinet for electronic apparatus in the first embodiment of the present invention. For example, as FIG. 1 shows, a bottom case 10 is employed as a cabinet for electronic apparatus on the bottom side of a portable, notebook electronic terminal 1. The bottom case 10 includes a plate of Mg—Li alloy having a low specific gravity. The combination of materials including magnesium and lithium of the alloy is not limited. That is, any type of Mg—Li alloy defined as, e.g., LZ91 or LA141, is available. From a viewpoint of reduction in weight and enhancement in rigidity of the cabinet, it is favorable to utilize LA141 having quite a low specific gravity.

The Mg—Li alloy for the bottom case 10 is prepared as below. Molten material including lithium, aluminum, and magnesium with predetermined percent by mass is cooled into an ingot of alloy. For the alloy ingot, a plastic process of a known method there is conducted. For example, rolling, forging, extruding, and drawing are carried out for the alloy ingot. Thereafter, an annealing process is conducted to re-crystallize the alloy deformed as a result of the plastic process. Finally, a surface treatment process is performed for the alloy to remove therefrom a surface oxide layer and a lithium segregation layer.

To obtain the bottom case 10, presswork such as drawing is conducted for the Mg—Li alloy, to form the alloy into the shape of a container. In the present embodiment, to reduce the cabinet in thickness, the plate thickness t (mm) of the bottom case 10 is set to 0.4≦t≦2.0 as shown in FIG. 2.

In the present embodiment, it is assumed in the presswork that the inner side of each bent portion formed between a plurality of surfaces of the bottom case 10 formed in the container shape has a radius of curvature R1. Description will be given of the bent portion by referring to the A-A cross-sectional view on a right-side surface of the bottom case 10 shown in FIG. 2.

In the cross-sectional view, a bent portion 10c is formed between a side surface portion 10a and a bottom surface portion 10b of the bottom case 10. In the present embodiment, the bottom case 10 is formed such that the plate thickness t (mm), the radius of curvature r (mm) on the inside of the bent portion 10c, and the height H1 (mm) of the side surface portion 10a satisfy relationships of the expressions below.

t≦r (1)

0<H1≦r+4 (2)

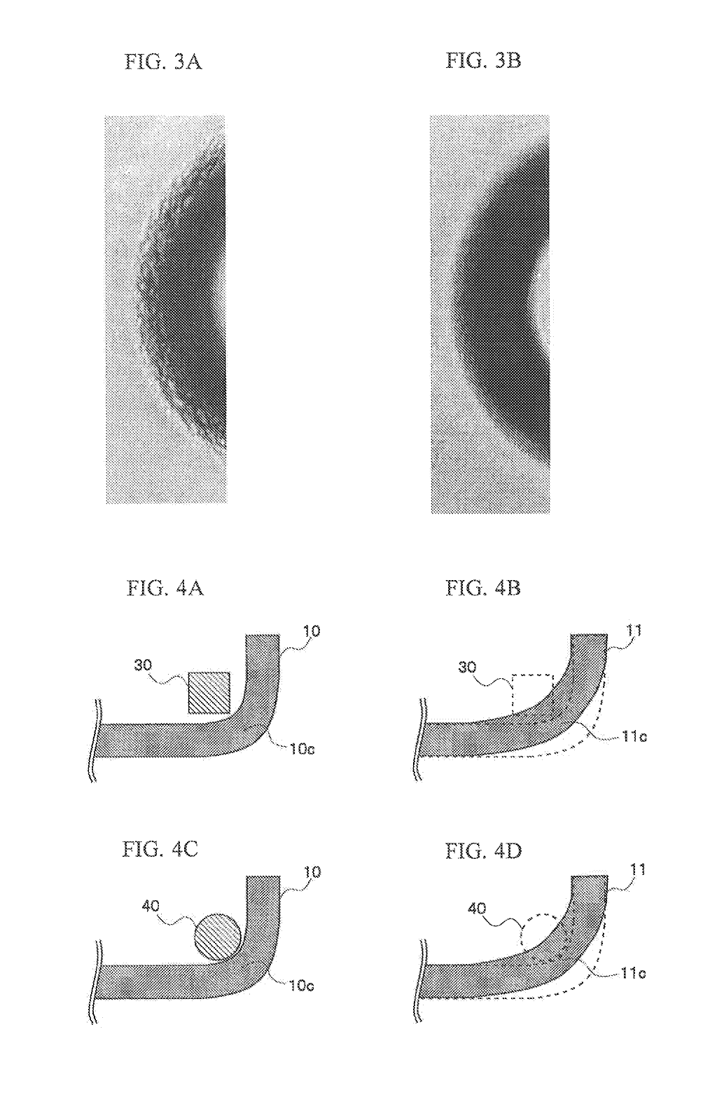

According to the present embodiment, when the radius of curvature r on the inside of the bent portion 10c is set to the lower-most value t of expression (1) or less, the material is non-uniformly extended in the bent portion 10c during the molding process of the cabinet. This leads to the phenomenon of rough surface in which the surface is not smooth, and the thickness of the bent portion 10c is locally reduced and a crack takes place. Hence, it is not possible to obtain a cabinet for electronic apparatus applicable to practical uses. FIG. 3A shows an image of a cabinet surface with a rough surface portion. FIG. 3B shows an image of a cabinet surface not including such rough surface portion.

To prevent the crack and the rough surface when molding the cabinet, it is desirable in the design that the height H1 of the side surface portion 10a is within the range of expression (2). According to expression (2), when the radius of curvature r on the inside of the bent portion 10c is smaller, the degree of deformation is larger in the angular portion of the cabinet material plate in the press molding process. Hence, there is a tendency that the height of the side surface portion 10a capable of preventing the crack and the rough surface in the molding process becomes smaller.

In other words, even when the plate thickness of the bottom case 10 is reduced to minimize the cabinet in thickness and weight as in the present embodiment, it is possible to prevent the rough surface and the crack in the bent portion of the bottom case 10 by molding the bottom case to satisfy expressions (1) and (2) in the presswork.

In the present embodiment, to prevent the rough surface and the crack, the upper-most value of the radius of curvature r of the bent portion 10c is not limited, but it is desirable that the value of r is 20.0 mm or less to secure the volume to accommodate various electronic parts and cords on boards in the cabinet.

For example, an electronic part 30 installable on the inside of the bent portion 10c of the bottom case 10 in which the radius of curvature r is 20.0 mm or less as shown in FIG. 4A cannot be easily mounted in the situation of FIG. 4B in which the radius of curvature r is more than 20.0 mm for the following reason. That is, due to the larger radius of curvature r, the inner wall of the bent portion 11c moves toward the inside of the cabinet and the volume to install the electronic part 30 is insufficient. Similarly, a cord or the like installable in the bottom case 10 in which the radius of curvature r is 20.0 mm or less as shown in FIG. 4C cannot be easily mounted in the bottom case 10 in which the radius of curvature r is more than 20.0 mm as shown in FIG. 4D.

### Second Embodiment

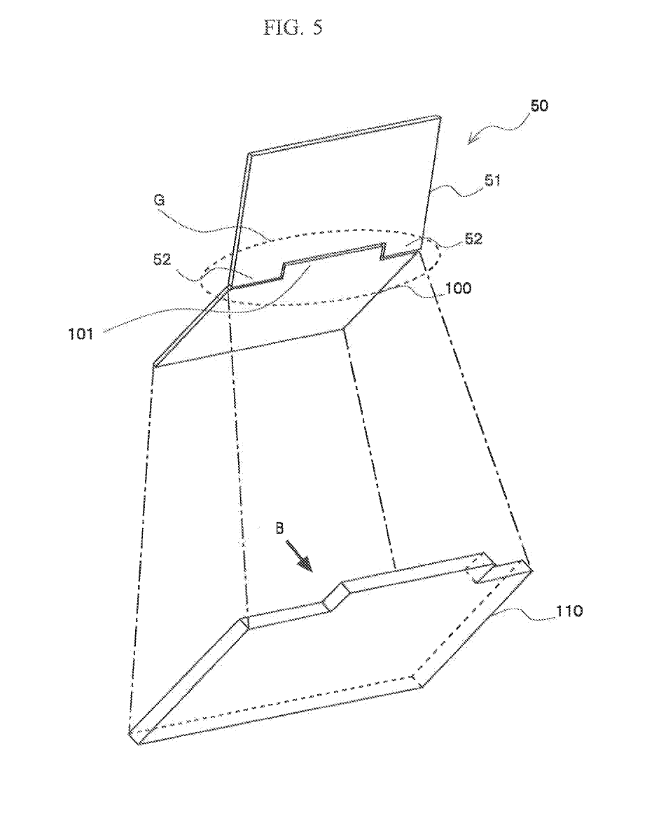

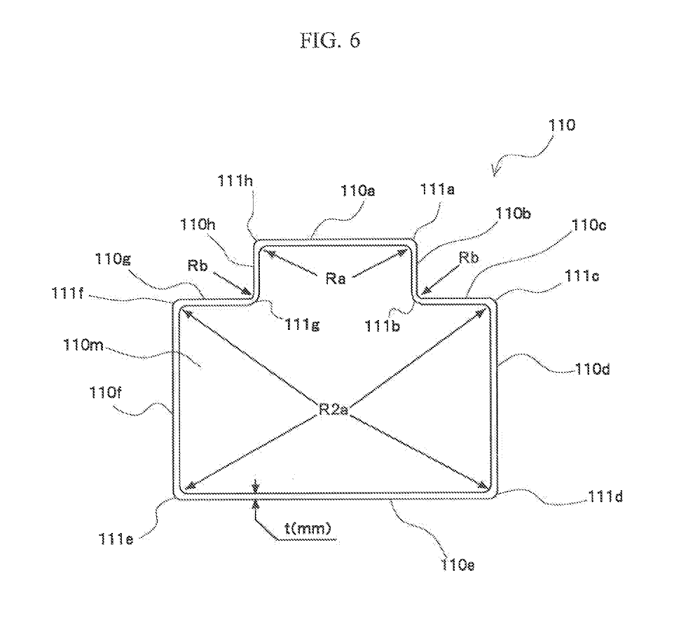

Referring next to FIGS. 5 and 6, description will be given of a cabinet for electronic apparatus in the second embodiment of the present invention. According to the second embodiment, as can be seen from FIG. 5, in a portable, notebook electronic terminal 50, a cabinet 51 on which a liquid-crystal display is mounted is rotably coupled via a hinge section G with a cabinet 100 including therein input devices such as a keyboard and electronic parts, e.g., a Central Processing Unit (CPU).

In the hinge section G, a projection-shaped hinge section 52 disposed on both lower sides of the cabinet 51 are engaged via a rotation mechanism, not shown, with a projection-shaped hinge section 101 disposed in an upper-central portion of the cabinet 100. In this configuration, a bottom case 110 with which the bottom surface of the cabinet 100 is covered has a contour projected upward for the hinge section 101 as shown in FIG. 5.

FIG. 6 shows, in a plan view, the bottom case 110 viewed from B in FIG. 5. The side surfaces vertically standing upward from the periphery of a bottom surface 110m of the bottom case 110 will be referred to, in the clockwise direction beginning at a hinge upper-side surface 110a; as a hinge right-side surface 110b, an upper-right surface 110c, a right-side surface 110d, a lower-side surface 110e, a left-side surface 110f, an upper-left surface 110g, and a hinge left-side surface 110h.

Through the process of drawing, there are formed bent portions on the boundaries between the side surfaces in addition to the bent portions between the bottom surface and the side surfaces of the bottom case described in conjunction with the first embodiment. Description will be given of how to derive an optimal radius of curvature for the bent portions between the side surfaces.

The bent portions formed on the boundaries between the side surfaces include a bent portion 111a (or a crest bent portion) between the hinge upper-side surface 110a and the hinge right-side surface 110b, a bent portion 111b (or a trough bent portion) between the hinge right-side surface 110b and the upper-right surface 110c, a bent portion 111c (or a crest bent portion) between the upper-side surface 110c and the right-side surface 110d, a bent portion 111d (or a crest bent portion) between the right-side surface 110d and the lower-side surface 110e, a bent portion 111e (or a crest bent portion) between the lower-side surface 110e and the lest-side surface 110f, a bent portion 111f (or a crest bent portion) between the left-side surface 110f and the upper-left surface 110g, a bent portion 111g (or a trough bent portion) between the upper-left surface 110g and the hinge left-side surface 110h, and a bent portion 111h (or a crest bent portion) between the hinge left-side surface 110h and the hinge upper-side surface 110a.

In the present embodiment, it is also required to prevent the rough surface and the crack in the respective bent portions. Through research and development made by the inventors, there have been derived relationships in the molding of the bottom case 110 as below for the plate thickness t (mm), the radius of curvature Ra (mm) on the inside of each crest bent portion of the cabinet, the height H2 (mm) of each side surface, the radius of curvature Rb (mm) on the outside of each trough bent portion of the cabinet, and the height H3 (mm) of each trough bent portion.

t≦Ra (4)

2t≦Rb (5)

0<H2≦Ra+4 (6)

0<H3≦Rb+2 (7)

Assume in the present embodiment that the radius of curvature Ra (mm) on the inside of each crest bent portion is equal to or less than the lower-most value t of expression (4) and the radius of curvature Rb (mm) on the outside of each trough bent portion of the cabinet is equal to or less than the lower-most value 2t of expression (5). Then, in the molding of the cabinet, the surface is not smooth due to non-uniform extension of the material in each bent portion, and the phenomenon of the rough surface takes place. Further, the thickness of the bent portion is locally reduced and a crack takes place. Hence, it is not possible to obtain a cabinet for electronic apparatus applicable to practical uses.

As in the first embodiment, it is required that the height H2 of each side surface satisfies expression (6). On the other hand, each trough bent portion is less in the height H3 than each side surface in the presswork. Hence, it is required that the height H3 satisfies expression (7).

That is, even when the plate thickness of the bottom case 110 is reduced to minimize the cabinet in thickness as in the present embodiment, it is possible to prevent the rough surface and the crack in the bent portions of the bottom case 10 by molding the bottom case to satisfy expressions (4) to (7) in the presswork. This makes it possible to optimally retain the mounting efficiency of parts integrally disposed in the bottom case. Also, it is possible to prevent interference in the cabinet hinge section.

As in the first embodiment, to prevent the rough surface and the crack, the upper-most value of the radius of curvature Ra on the inside of each crest bent portion of the cabinet is not limited. However, it is desirable that the value of Ra is 30.0 mm or less to fully secure the area to accommodate components required to achieve functions of the electronic apparatus such as various boards, a liquid-crystal panel, a battery, and the like.

Similarly, the upper-most value of the radius of curvature Rb on the outside of each trough bent portion of the cabinet is desirably set to 30.0 mm or less. For example, when the radius of curvature Ra or Rb exceeds 30.0 mm, there occurs a problem that the screen of the liquid-crystal panel installed in the cabinet is reduced by one inch or more.

Actually, the cabinet for portable electronic terminal may include a plurality of contours described above. Further, for example, the rising angle of the bent portion (rising wall) between the side surface and the bottom surface is not necessarily an angle to form a vertically rising wall only if there does not appear a situation of undercut in which the angle between the side surface and the bottom surface is acute.

### Embodiments

Description will be given of embodiments of the present invention. In each embodiment, “San Maria” of Santoku is employed as the Mg—Li alloy. As conditions to mold the cabinet, the metallic mold temperature is adjusted in a range from the room temperature to 300° C. and a servo press or the like is employed.

For results of the molding, verification is conducted on each press sample molded as a cabinet for a personal computer having a vertical length of about 200 mm and a longitudinal length of about 300 mm. The cabinet is molded at a metallic mold temperature ranging from 100° C. to 300° C. At any mold temperature, each of the obtained cabinets satisfies the expressions described above.

### [Verification of Rough Surface and Crack]

In each embodiment, presence or absence of the rough surface is confirmed by viewing an image of a bent portion after the presswork, the image being magnified by a microscope. Also, presence or absence of the crack is visually confirmed in a similar fashion. Results of the confirmation are presented as “good” when neither the rough surface nor the crack takes place, “rough surface” or “crack” when either one of the rough surface and the crack is present, and “rough surface and crack” when both thereof take place.

First, in a situation wherein the plate thickness of the cabinet is 0.4 mm in the bent portion between the bottom surface and the side surface, verification is conducted for the rough surface and the crack by using embodiments and comparison examples in which “radius of curvature r on the inside between the bottom surface and the side surface” and “height H1 of the side surface” are changed. Results of the verification are listed in Table 1 as below.

TABLE 1

| | | r | H1 | Press performance judge result |
|---|---|---|---|---|
| Embodiment | 1 | 0.4 | 4.4 | Good |
| | 2 | 0.5 | 4.4 | Good |
| | 3 | 1.0 | 4.4 | Good |
| | 4 | 10.0 | 14.0 | Good |
| | 5 | 20.0 | 24.0 | Good |
| Comparison | 1 | 0.2 | 4.4 | Rough surface and crack |
| example | 2 | 0.3 | 4.4 | Rough surface |
| | 3 | 0.4 | 5.0 | Rough surface and crack |
| | 4 | 20.0 | 26.0 | Rough surface and crack |

In embodiment 1, r is 0.4 mm and H1 is 4.4 mm. In embodiment 2, r is 0.5 mm and H1 is 4.4 mm. In embodiment 3, r is 1.0 mm and H1 is 4.4 mm. In embodiment 4, r is 10.0 mm and H1 is 14.0 mm. In embodiment 5, r is 20.0 mm and H1 is 24.0 mm. According to verification, the press performance judge result is “good” for each of embodiments 1 to 5.

In comparison example 1 in which r is 0.2 mm and H1 is 4.4 mm, there appears “rough surface and crack”. In comparison example 2 in which r is 0.3 mm and H1 is 4.4 mm, “rough surface” takes place. In comparison example 3 in which r is 0.4 mm and H1 is 5.0 mm, there appears “rough surface and crack”. In comparison example 4 in which r is 20.0 mm and H1 is 26.0 mm, “rough surface and crack” takes place.

Next, in a situation wherein the plate thickness of the cabinet is 2.0 mm in the bent portion between the bottom surface and the side surface, verification is conducted for the rough surface and the crack by using embodiments and comparison examples in which “radius of curvature r on the inside between the bottom surface and the side surface” and “height H1 of the side surface” are changed. Results of the verification are listed in Table 2 as below.

TABLE 2

| | | r | H1 | Press performance judge result |
|---|---|---|---|---|
| Embodiment | 6 | 2.0 | 6.0 | Good |
| | 7 | 2.5 | 6.0 | Good |
| | 8 | 3.0 | 6.0 | Good |
| | 9 | 10.0 | 14.0 | Good |
| | 10 | 20.0 | 24.0 | Good |
| Comparison | 5 | 1.0 | 6.0 | Rough surface and crack |
| example | 6 | 1.5 | 6.0 | Rough surface |
| | 7 | 2.0 | 8.0 | Rough surface and crack |
| | 8 | 20.0 | 26.0 | Rough surface and crack |

In embodiment 6, r is 2.0 mm and H1 is 6.0 mm. In embodiment 7, r is 2.5 mm and H1 is 6.0 mm. In embodiment 8, r is 3.0 mm and H1 is 6.0 mm. In embodiment 9, r is 10.0 mm and H1 is 14.0 mm. In embodiment 10, r is 20.0 mm and H1 is 24.0 mm. According to verification, the press performance judge result is “good” for each of embodiments 6 to 10.

In comparison example 5 in which r is 1.0 mm and H1 is 6.0 mm, there appears “rough surface and crack”. In comparison example 6 in which r is 1.5 mm and H1 is 6.0 mm, “rough surface” takes place. In comparison example 7 in which r is 2.0 mm and H1 is 8.0 mm, there appears “rough surface and crack”. In comparison example 8 in which r is 20.0 mm and H1 is 26.0 mm, “rough surface and crack” takes place.

Further, in a situation wherein the plate thickness of the cabinet is 0.4 mm in the crest bent portion between the side surfaces, verification is conducted for the rough surface and the crack by using embodiments and comparison examples in which “radius of curvature r on the inside between the bottom surface and the side surface”, “the radius of curvature Ra on the inside of the crest bent portion”, and “height H2 of the side surface in the crest bent portion” are changed. Results of the verification are listed in Table 3 as below.

TABLE 3

| | | r | Ra | H2 | Press performance judge result |
|---|---|---|---|---|---|
| Embodiment | 11 | 0.4 | 0.4 | 4.4 | Good |
| | 12 | 0.4 | 1.0 | 4.4 | Good |
| | 13 | 0.4 | 30.0 | 4.4 | Good |
| | 14 | 20.0 | 30.0 | 24.0 | Good |
| Comparison | 9 | 0.4 | 0.2 | 4.4 | Rough surface and crack |
| example | 10 | 0.4 | 0.3 | 4.4 | Rough surface |
| | 11 | 0.4 | 0.4 | 5.0 | Rough surface and crack |
| | 12 | 0.4 | 30.0 | 34.0 | Rough surface and crack |

In embodiment 11, r is 0.4 mm, Ra is 0.4 mm, and H2 is 4.4 mm. In embodiment 12, r is 0.4 mm, Ra is 1.0 mm, and H2 is 4.4 mm. In embodiment 13, r is 0.4 mm, Ra is 30.0 mm, and H2 is 4.4 mm. In embodiment 14, r is 20.0 mm, Ra is 30.0 mm, and H2 is 24.0 mm. According to verification, the press performance judge result is “good” for each of embodiments 11 to 14.

In comparison example 9 in which r is 0.4 mm, Ra is 0.2 mm, and H2 is 4.4 mm, there appears “rough surface and crack”. In comparison example 10 in which r is 0.4 mm, Ra is 0.3 mm, and H2 is 4.4 mm, “rough surface” takes place. In comparison example 11 in which r is 0.4 mm, Ra is 0.4 mm, and H2 is 5.0 mm, there appears “rough surface and crack”. In comparison example 12 in which r is 0.4 mm, Ra is 30.0 mm, and H2 is 34.0 mm, “rough surface and crack” takes place.

Next, in a situation wherein the plate thickness of the cabinet is 2.0 mm in the crest bent portion between the side surfaces, verification is conducted for the rough surface and the crack by using embodiments and comparison examples in which “radius of curvature r on the inside between the bottom surface and the side surface”, “the radius of curvature Ra on the inside of the crest bent portion”, and “height H2 of the side surface in the crest bent portion” are changed. Results of the verification are listed in Table 4 as below.

TABLE 4

| | | r | Ra | H2 | Press performance judge result |
|---|---|---|---|---|---|
| Embodiment | 15 | 2.0 | 2.0 | 6.0 | Good |
| | 16 | 2.0 | 3.0 | 6.0 | Good |
| | 17 | 2.0 | 30.0 | 6.0 | Good |
| | 18 | 20.0 | 30.0 | 24.0 | Good |
| Comparison | 13 | 2.0 | 1.0 | 6.0 | Rough surface and crack |
| example | 14 | 2.0 | 1.5 | 6.0 | Rough surface |
| | 15 | 2.0 | 0.4 | 8.0 | Rough surface and crack |
| | 16 | 2.0 | 30.0 | 34.0 | Rough surface and crack |

In embodiment 15, r is 2.0 mm, Ra is 2.0 mm, and H2 is 6.0 mm. In embodiment 16, r is 2.0 mm, Ra is 3.0 mm, and H2 is 6.0 mm. In embodiment 17, r is 2.0 mm, Ra is 30.0 mm, and H2 is 6.0 mm. In embodiment 18, r is 20.0 mm, Ra is 30.0 mm, and H2 is 24.0 mm. According to verification, the press performance judge result is “good” for each of embodiments 15 to 18.

In comparison example 13 in which r is 2.0 mm, Ra is 1.0 mm, and H2 is 6.0 mm, there appears “rough surface and crack”. In comparison example 14 in which r is 2.0 mm, Ra is 1.5 mm, and H2 is 6.0 mm, “rough surface” takes place. In comparison example 15 in which r is 2.0 mm, Ra is 0.4 mm, and H2 is 8.0 mm, there appears “rough surface and crack”. In comparison example 16 in which r is 2.0 mm, Ra is 30.0 mm, and H2 is 34.0 mm, “rough surface and crack” takes place.

Further, in a situation wherein the plate thickness of the cabinet is 0.4 mm in the trough bent portion between the side surfaces, verification is conducted for the rough surface and the crack by using embodiments and comparison examples in which “radius of curvature r on the inside between the bottom surface and the side surface”, “the radius of curvature Rb on the outside of the trough bent portion”, and “height H3 of the side surface in the trough bent portion” are changed. Results of the verification are listed in Table 5 as below.

TABLE 5

| | | r | Rb | H3 | Press performance judge result |
|---|---|---|---|---|---|
| Embodiment | 19 | 0.4 | 0.8 | 2.8 | Good |
| | 20 | 0.4 | 1.0 | 2.8 | Good |
| | 21 | 0.4 | 30.0 | 2.8 | Good |
| | 22 | 20.0 | 30.0 | 22.0 | Good |
| Comparison | 17 | 0.4 | 0.4 | 2.8 | Rough surface and crack |
| example | 18 | 0.4 | 0.6 | 2.8 | Rough surface |
| | 19 | 0.4 | 0.8 | 4.0 | Rough surface and crack |
| | 20 | 0.4 | 30.0 | 34.0 | Rough surface and crack |

In embodiment 19, r is 0.4 mm, Rb is 0.8 mm, and H3 is 2.8 mm. In embodiment 20, r is 0.4 mm, Rb is 1.0 mm, and H3 is 2.8 mm. In embodiment 21, r is 0.4 mm, Rb is 30.0 mm, and H3 is 2.8 mm. In embodiment 22, r is 20.0 mm, Rb is 30.0 mm, and H3 is 22.0 mm. According to verification, the press performance judge result is “good” for each of embodiments 19 to 22.

In comparison example 17 in which r is 0.4 mm, Rb is 0.4 mm, and H3 is 2.8 mm, there appears “rough surface and crack”. In comparison example 18 in which r is 0.4 mm, Rb is 0.6 mm, and H3 is 2.8 mm, “rough surface” takes place. In comparison example 19 in which r is 0.4 mm, Rb is 0.8 mm, and H3 is 4.0 mm, there appears “rough surface and crack”. In comparison example 20 in which r is 0.4 mm, Rb is 30.0 mm, and H3 is 34.0 mm, “rough surface and crack” takes place.

Next, in a situation wherein the plate thickness of the cabinet is 2.0 mm in the trough bent portion between the side surfaces, verification is conducted for the rough surface and the crack by using embodiments and comparison examples in which “radius of curvature r on the inside between the bottom surface and the side surface”, “the radius of curvature Rb on the outside of the trough bent portion”, and “height H3 of the side surface in the trough bent portion” are changed. Results of the verification are listed in Table 6 as below.

TABLE 6

| | | r | Rb | H3 | Press performance judge result |
|---|---|---|---|---|---|
| Embodiment | 23 | 2.0 | 4.0 | 6.0 | Good |
| | 24 | 2.0 | 5.0 | 6.0 | Good |
| | 25 | 2.0 | 30.0 | 6.0 | Good |
| | 26 | 20.0 | 30.0 | 22.0 | Good |
| Comparison | 21 | 2.0 | 1.0 | 6.0 | Rough surface and crack |
| example | 22 | 2.0 | 2.0 | 6.0 | Rough surface |
| | 23 | 2.0 | 4.0 | 8.0 | Rough surface and crack |
| | 24 | 2.0 | 30.0 | 34.0 | Rough surface and crack |

In embodiment 23, r is 2.0 mm, Rb is 4.0 mm, and H3 is 6.0 mm. In embodiment 24, r is 2.0 mm, Rb is 5.0 mm, and H3 is 6.0 mm. In embodiment 25, r is 2.0 mm, Rb is 30.0 mm, and H3 is 6.0 mm. In embodiment 26, r is 20.0 mm, Rb is 30.0 mm, and H3 is 22.0 mm. According to verification, the press performance judge result is “good” for each of embodiments 23 to 26.

In comparison example 21 in which r is 2.0 mm, Rb is 1.0 mm, and H3 is 6.0 mm, there appears “rough surface and crack”. In comparison example 22 in which r is 2.0 mm, Rb is 2.0 mm, and H3 is 6.0 mm, “rough surface” takes place. In comparison example 23 in which r is 2.0 mm, Rb is 4.0 mm, and H3 is 8.0 mm, there appears “rough surface and crack”. In comparison example 24 in which r is 2.0 mm, Rb is 30.0 mm, and H3 is 34.0 mm, “rough surface and crack” takes place.

As can be seen from the verification results, when expressions (1) to (7) of the embodiments of the present invention are satisfied, it is possible to obtain a cabinet for electronic apparatus in which neither the rough surface nor the crack takes place in any bent portion of the cabinet.

The present invention is applicable to cabinets for electronic apparatuses such as a notebook personal computer, a mobile terminal, and a slate terminal as well as to cabinets for white home appliances, cars, machines for industrial uses, toys, and the like.

It will be understood by those of ordinary skill in the art that various changes in form and details may be made therein without departing from the spirit and scope of the present invention as defined claims.

What is claimed is:

1. A cabinet for electronic apparatus comprising at least one surface formed by conducting presswork for magnesium-lithium alloy, wherein:
the surface has a plate thickness t (mm) in a range of 0.4≦t≦2.0;
at least one bent portion between at least two of the surfaces has a radius of curvature r (mm) on an inside of the bent portion in a range of t≦r; and
at least one side surface standing relative to a bottom surface selected from the surfaces has a height H (mm) in a range of 0≦H≦r+4.

2. A cabinet for electronic apparatus in accordance with claim 1, wherein at least one bent portion between a bottom surface selected from the surfaces and at least one side surface standing relative to a bottom surface selected from the surfaces has a radius of curvature r (mm) on an inside of the bent portion in a range of t≦r.

3. A cabinet for electronic apparatus in accordance with claim 2, wherein:
at least one crest bent portion formed between at least two of the surfaces has a radius of curvature Ra (mm) on an inside of the cabinet in a range of t≦Ra; and
the at least one crest bent portion has a radius of curvature H (mm) in a range of 0≦H≦Ra+4.

4. A cabinet for electronic apparatus in accordance with claim 2, wherein:
at least one trough bent portion formed between at least two of the surfaces has a radius of curvature Rb (mm) on an outside of the cabinet in a range of 2t≦Rb; and
the at least one trough bent portion has a radius of curvature H (mm) in a range of 0≦H≦Rb+2.

5. A cabinet for electronic apparatus in accordance with claim 3, wherein:
at least one trough bent portion formed between at least two of the surfaces has a radius of curvature Rb (mm) on an outside of the cabinet in a range of 2t≦Rb; and
the at least one trough bent portion has a radius of curvature H (mm) in a range of 0≦H≦Rb+2.

6. An electronic apparatus comprising a cabinet for electronic apparatus in accordance with claim 1.

7. An electronic apparatus comprising a cabinet for electronic apparatus in accordance with claim 2.

8. An electronic apparatus comprising a cabinet for electronic apparatus in accordance with claim 3.

9. An electronic apparatus comprising a cabinet for electronic apparatus in accordance with claim 4.

10. An electronic apparatus comprising a cabinet for electronic apparatus in accordance with claim 5.
